(19) United States
(12) Patent Application Publication
(10) Pub. No.: US 2005/0146048 A1
(43) Pub. Date: Jul. 7, 2005

(54) Damascene interconnect structures

(76) Inventors: Valery M. Dubin, Portland, OR (US); Peter K. Moon, Portland, OR (US); Kevin P. O'Brien, Portland, OR (US)

Correspondence Address: SCHWABE, WILLIAMSON & WYATT, P.C.;PACWEST CENTER, SUITES 1600-1900, 1211 SW FIFTH AVENUE, PORTLAND, OR, 97204, US

(21) Appl. No.: 10/748,359

(22) Filed: Dec. 30, 2003

(51) Int. Cl. H01L 23/48

(52) U.S. Cl. 257/774

(57) ABSTRACT

A method for making a semiconductor device is provided including providing a substrate, and forming a dielectric layer over the substrate. The method also includes defining a damascene interconnect structure in the dielectric layer and forming a barrier layer over the dielectric layer and within the damascene interconnect structure where the barrier layer is tapered within the damascene interconnect structure.

### FIELD OF THE INVENTION

The present invention relates to the manufacture of semiconductor devices and, more particularly, to gap filling of damascene interconnect structures.

### BACKGROUND OF INVENTION

Semiconductor processing is an important part of generating semiconductor devices. Within semiconductor processing, damascene interconnect structures such as, for example, vias and/or trenches are often filled with a variety of materials.

Therefore, there is a need to gap fill damascene interconnect structures in an efficient and effective manner.

### BRIEF DESCRIPTION OF THE DRAWINGS

Embodiments of the present invention will be readily understood by the following detailed description in conjunction with the accompanying drawings. To facilitate this description, like reference numerals designate like structural elements. The invention is illustrated by way of example and not by way of limitation in the figures of the accompanying drawings.

FIG. 1 shows a substrate upon which a dielectric layer has been deposited in accordance with one embodiment of the present invention..

FIG. 2 illustrates a photoresist mask formed over the dielectric layer in accordance with one embodiment of the present invention.

FIG. 3 illustrates the photoresist mask after patterning in accordance with one embodiment of the present invention.

FIG. 4 illustrates the substrate after etching of the exposed regions in accordance with one embodiment of the present invention.

FIG. 5 illustrates a substrate after a barrier layer has been deposited over the dielectric layer in accordance with one embodiment of the present invention.

FIG. 6 illustrates a substrate where a metal layer has been deposited in accordance with one embodiment of the present invention.

FIG. 7 illustrates a substrate where a metal layer partially fills the vias in accordance with one embodiment of the present invention.

FIG. 8 shows a damascene interconnect structure with tapered via with a cap/cladding layer in accordance with one embodiment of the present invention.

FIG. 9 shows a flowchart illistrating a generation of a semiconductor device with a tapered barrier layer within a damascene interconnect structure in accordance with one embodiment of the present invention.

FIG. 10 shows a damascene interconnect structure in a computing system in accordance with one embodiment of he present invention.

### DETAILED DESCRIPTION OF EMBODIMENTS OF THE INVENTION

In the following detailed description, reference is made to the accompanying drawings which form a part hereof wherein like numerals designate like parts throughout, and in which is shown by way of illustration specific embodiments in which the invention may be practiced. It is to be understood that other embodiments may be utilized and structural or logical changes may be made without departing from the scope of the present invention. Therefore, the following detailed description is not to be taken in a limiting sense, and the scope of the present invention is defined by the appended claims and their equivalents.

The embodiments of the present invention enable generation of semiconductor devices using the application of a tapered barrier layer into vias where the barrier layer is thinner toward an edge of the via and thicker toward the bottom of the via. This may be accomplished by either plasma etching or chemical etching in conjunction with the application of a voltage potential. This increases the electrical field strength at the edges of the vias which enhances the etching of the barrier layer. In such embodiments, the tapered barrier layer within the damascene interconnect structures such as, for example, vias and trenches may be filled without the problems of metal overhang or incomplete via sidewall material deposition. It should be appreciated that as utilized within, the damascene interconnect structure may be any suitable gap that can have the tapered barrier layer.

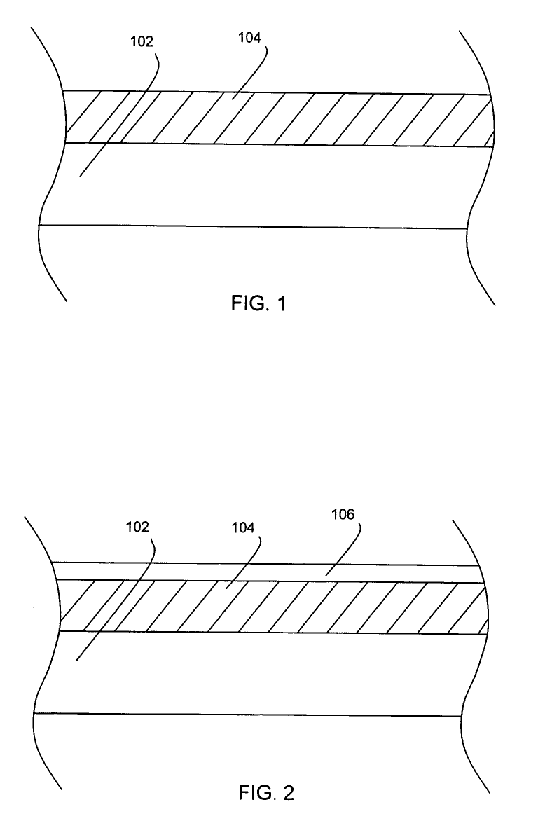

FIGS. 1 though 8 illustrate a progression of stages of semiconductor device processing that enable the generation of a tapered barrier layer within a damascene interconnect structure. It should be appreciated that FIGS. 1 through 5 are exemplary in nature and that the methods described herein to generate a tapered layer within the damascene structure may be applied to generate any suitable type of semiconductor structure.

FIG. 1 shows a substrate 102 upon which a dielectric layer 104 has been deposited in accordance with one embodiment of the present invention. Although in one embodiment, the dielectric layer 104 has been illustrated as being over the substrate 102, the dielectric layer 104 may be any suitable layer in a multilayer semiconductor stack.

In another embodiment, the dielectric layer 104 may be an uppermost layer of a metallization stack deposited on a semiconductor wafer. It should be appreciated that the dielectric layer 104 may be any suitable flexible or rigid polymer substrate. In one embodiment, the dielectric layer 104 may be a silicon based substance such as, for example, silicon dioxide, low K dielectrics, etc. In another embodiment, the dielectric layer 104 may include a ceramic material such as, for example, silicon carbide, aluminum nitride, aluminum oxide. In addition, the dielectric layer may be any suitable thickness depending on the semiconductor structure desired.

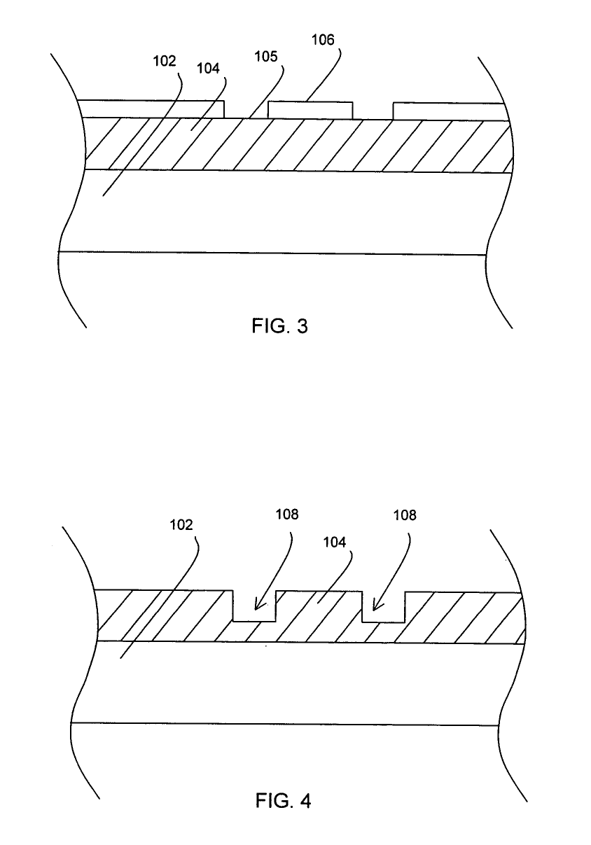

FIG. 2 illustrates a photoresist mask 106 formed over the dielectric layer 104 in accordance with one embodiment of the present invention. In one embodiment, the photoresist mask 106 is deposited over the dielectric layer 104. It should be appreciated that any suitable type of photoresist mask 106 as known to those skilled in the art may be made using any suitable type of photoresist material.

FIG. 3 illustrates the photoresist mask 106 after patterning in accordance with one embodiment of the present invention. In one embodiment, the patterning of the photoresist mask 106 leaves exposed regions 105. It should be appreciated that any suitable type of patterning may be utilized depending on the structure desired. In one embodiment, the patterning forms an exposed outline of a feature over the dielectric layer. It should be understood that the photoresist mask 106 may be applied and utilized in accordance with generally accepted methods as known by one skilled in the art. The photoresist mask 106 may then be patterned utilizing any type of light source capable of patterning the photoresist mask 106. In one embodiment, a UV light source may be applied to certain portions of the photoresist mask 106 in a pattern desired.

Generally, exposure to certain forms of light changes the chemical composition of the exposed regions of the photoresist mask 106 enabling the developing of photoresist mask 106. After the photoresist 106 has been patterned and developed to show the exposed regions 105 which in one embodiment is a top surface of the dielectric layer 104, etching may be conducted as described in reference to FIG. 4.

FIG. 4 illustrates the substrate 102 after etching of the exposed regions 105 in accordance with one embodiment of the present invention. In one embodiment, after the photoresist mask 106 has been patterned as described in reference to FIG. 3, the exposed regions 105 may be etched thereby defining a damascene interconnect structure such as, for example, a via 108. It should be appreciated that other types of damascene interconnect structures in the dielectric layer 104 may be made using photolithography and etching such as trenches, etc.

The etch operation may be configured to etch dielectric materials, such as SiO₂, and the etching may be performed in a plasma etch chamber or in another suitable type of etching device such as, for example, a chemical etching chamber. After the etching has been completed, the photoresist mask 106 may then be removed utilizing a photoresist dissolving chemical that does not attack the dielectric layer 104. Any photoresist dissolving chemical as known to those skilled in the art may be utilized.

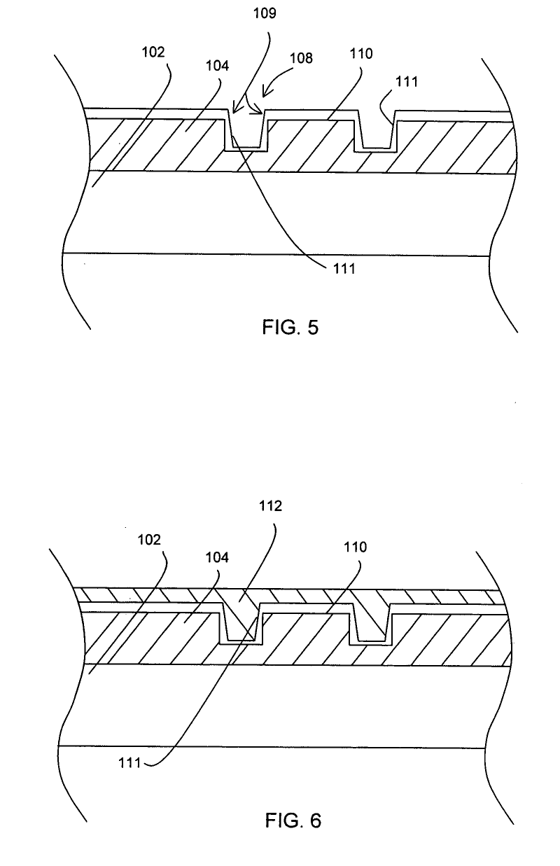

FIG. 5 illustrates a substrate 102 after a barrier layer 110 has been deposited over the dielectric layer 104 in accordance with one embodiment of the present invention. In one embodiment, after the via 108 (or the trench) has been defined in the dielectric layer 104, the barrier layer 110 may be deposited. In one embodiment, the barrier layer 110 may be deposited by physical vapor deposition (CVD)/sputtering or any other suitable manner. The barrier layer 110 may be any suitable material such as, for example, Ta(N), W(N), TiN, TiNSi, Co, Ni, Ru, Nb, Rh, any combination thereof, or any other suitable type of material. In one embodiment, the barrier layer 110 has a low resistivity (<100 uOhm cm) with a thickness of between 100 A and 500 A and made from a material such as, for example, αTa, W, Ru, Rh, Co, Ni, etc. In another embodiment, the barrier layer 110 may be between 200 A and 250 A. The thickness of the barrier layer 110 may be varied depending on the strength of the dielectric layer 104. If tantalum (Ta) is utilized as the barrier layer 110, a thick copper seed layer may be deposited before a copper layer is formed over the barrier layer 1 10 to improve adhesion of plated copper.

In one embodiment, the barrier layer 110 in the via 108 is tapered by application of voltage to produce a negative potential on the substrate 102 during etching of the barrier layer 1 10 at substantially the same time the barrier layer 1 10 is being deposited. In another embodiment, the barrier layer 110 is etched while the negative potential is applied to the substrate 102 after the deposition of the barrier layer 110.

When the voltage is applied to the substrate 102 during the etching process, the electrical field generated on the substrate 102 is stronger at the edges 109 of the via 108 than at other locations. Therefore, the etching of the barrier layer is 1 10 is enhanced at the via edges and therefore, the resulting barrier layer is thinner around the edges of the via 108 as opposed to other portions of the barrier layer 108. As a result, a tapered wall of the barrier layer 110 is generated along the walls of the via 108 because the etching is greater at the edges and etching decreases further down the walls of the via 108. This generates a thinner to thicker profile from a top portion of the via 108 to a bottom portion of the via 108.

In one embodiment, the voltage may be applied to the substrate through a wafer holder that is holding the substrate 102. It should be appreciated that the voltage may be applied to the substrate 102 through any apparatus that may be holding the substrate 102. The wafer holder may be any suitable type of wafer holder such as, for example, a wafer carrier, a chuck, etc. as long as the wafer holder is configured to be capable of applying a voltage to the substrate 102. In one embodiment, a voltage source may be connected to wafer holder contacts on the wafer holder. In such a manner, the wafer holder contacts can then apply the voltage to the substrate 102. The tapering of the barrier layer 110 advantageously configures the via 108 such that other layers deposited over the barrier layer 110 do not overhang on the edges of the vias 108. In addition, a tapered barrier layer region 111 avoids poor sidewall coverage during deposition of material in the via 108.

In one embodiment, the tapered barrier layer region 111 may be generated by applying a negative potential while the tapered barrier layer region 111 is etched by plasma such as, for example, positive Argon ions. It should be appreciated that Argon ions are one type of plasma and any other suitable type of plasma may be utilized. In one embodiment, the voltage applied to the substrate 102 may be between 50 V to 150 V although any other suitable voltages may be utilized as long as the tapered barrier layer within the via walls may be generated.

In another embodiment, the tapered barrier layer region 111 may be generated by applying a positive potential while the tapered barrier region 111 is chemically etched. The chemical etching operation described herein may also be called electrochemical etching. It should be appreciated that any suitable type of chemical may be utilized that can etch barrier layer materials and whose etching effectiveness may be altered by the application of electrical fields. In one embodiment a basic solution such as, for example, HF, nitric acid, sulfuric acid, etc., may be utilized as the chemical etchant in the etching operation. In one embodiment, the voltage applied to the substrate 102 during the chemical etching operation may be between 1 V and 10 V although other voltages that can generate the tapered barrier layer may be utilized.

FIG. 6 illustrates a substrate 102 where a metal layer 112 has been deposited in accordance with one embodiment of the present invention. In one embodiment, the metal layer 112 is formed over the structure so as to fully fill the via 108. It should be appreciated that any suitable type of metal deposition may be utilized. In one embodiment, conformal deposition such as, for example, electroless plating, electroplating from a basic solution, atomic layer deposition (ALD), or chemical vapor deposition (CVD) may be utilized. The metal layer 112 may be any desired metal such as, for example, a copper layer. A seed layer (not shown) may be optionally deposited over the barrier layer 110 when the barrier layer 110 is a tantalum layer and copper is utilized as the metal layer 112.

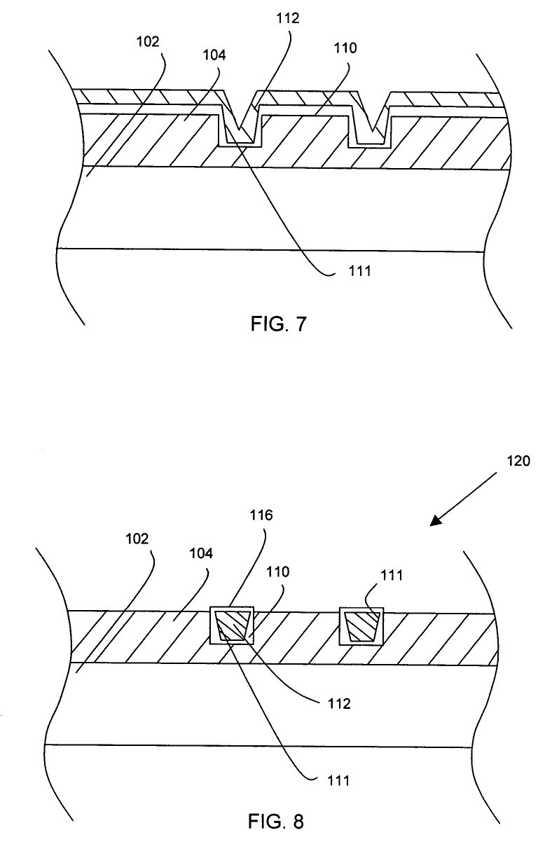

FIG. 7 illustrates a substrate 102 where a metal layer 112′ partially fills the vias in accordance with one embodiment of the present invention. In one embodiment, the metal layer 112′ is a copper layer although any other suitable metal may be utilized. The metal layer 112′, in this embodiment, partially fills the via when such a structure is desired. The copper layer may be applied in any suitable manner as described in reference to FIG. 6.

FIG. 8 shows a damascene interconnect structure 120 with a tapered via with a cap/cladding layer 116 in accordance with one embodiment of the present invention. In one embodiment, the structure 120 is generated when the structure as shown in FIG. 6 is planarized down to the dielectric layer 104 and a cap/cladding layer 116 is applied over the dielectric layer and the metal layer 112 remaining in the via 108. In one embodiment, the cap/cladding layer may be any suitable material such as, for example, Co, W, Ta, Ti, Pd, and their alloys and metalloids.

Therefore, by applying a bias such as a negative potential or a positive potential to the substrate 102, etching of the barrier layer 110 may be increased at the edge region of the via due to the stronger electrical field in that region. Consequently, after the etching operation, the barrier layer 110 within the via defined into the dielectric layer 104 is thinner at the edge of the via and becomes thicker as the barrier layer 110 gets closer to the bottom of the via. In this fashion, a tapered barrier layer may be generated within the via 108. As a result, layers such as the metal layer 112 may be applied to the via 108 without the problems of overhang or insufficient sidewall deposition.

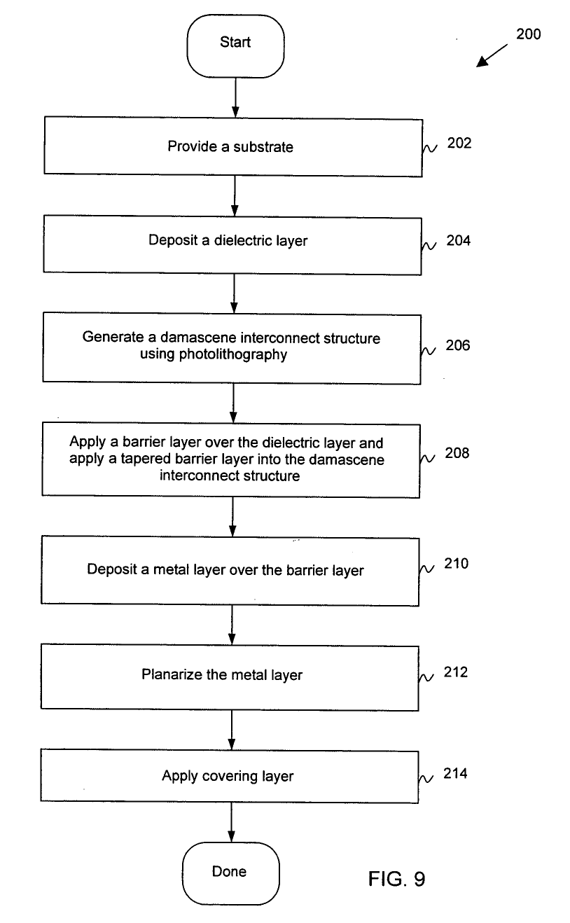

FIG. 9 shows a flowchart 200 illustrating a generation of a semiconductor device with a tapered barrier layer within a damascene interconnect structure in accordance with one embodiment of the present invention. In one embodiment, the method begins with operation 202 which provides a substrate as discussed in reference to FIG. 1. After operation 202, the method moves to operation 204 which deposits a dielectric layer as described in further detail in reference to FIG. 2. Then the method advances to operation 206 where a damascene interconnect structure such as, for example, a via or a trench is generated using photolithography as described in reference to FIGS. 3 and 4. After operation 206, the method moves to operation 208 which applies a barrier layer over the dielectric layer and applies a tapered barrier layer into the damascene interconnect structure such as described in reference to FIG. 5. Then operation 210 optionally deposits a metal layer over the barrier layer. After operation 210, the method proceeds to operation 212 which optionally planarizes the metal layer. Then operation 214 optionally applies a covering layer. This may result in the structure as discussed in reference to FIG. 8. In one embodiment, the method as described herein may be repeated as many times as desired to form further interconnect layers.

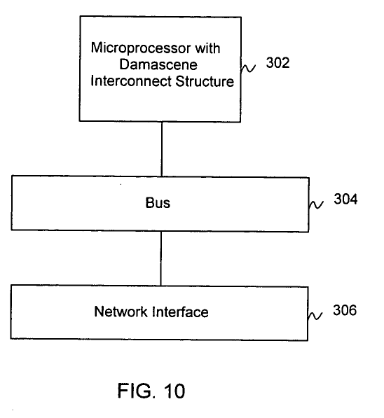

FIG. 10 shows a damascene interconnect structure in a computing system 300 in accordance with one embodiment of the present invention. In one embodiment, the system 300 includes a microprocessor 302 including the damascene interconnect structure. It should be appreciated that the microprocessor 302 may include any suitable number and/or structure of the damascene interconnect structure consistent with what is described herein in reference to FIGS. 1-9 above where a tapered barrier layer is utilized. In addition, the tapered barrier layer may be generated using the methods described herein in reference to FIGS. 1-9. The microprocessor 302 may be coupled to a bus 304 which in turn may be coupled to a network interface 306. It should be appreciated that the damascene interconnect structure may be utilized in any suitable microprocessor device attached to any suitable number or types of computing devices. It should also be understood that the microprocessor 302 may be coupled to the bus 304 and the bus 304 may be coupled to the network interface 306 in any suitable fashion.

Although specific embodiments have been illustrated and described herein for purposes of description of preferred embodiments, it will be appreciated by those of ordinary skill in the art that a wide variety of alternate and/or equivalent implementations calculated to achieve the same purposes may be substituted for the specific embodiment shown and descripbed without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

1. A semiconductor device, comprising:
a substrate;
a dielectric layer formed over the substrate;
a damascene interconnect structure defined in the dielectric layer; and
a barrier layer deposited over the dielectric layer and within the damascene interconnect structure, the barrier layer within the damascene interconnect structure being tapered.

2. A semiconductor device as recited in claim 1, wherein the barrier layer is tapered within the damascene interconnect structure so the barrier layer is thinner toward an edge of the damascene interconnect structure and thicker toward a bottom portion of the damascene interconnect structure.

3. A semiconductor device as recited in claim 1, wherein the damascene interconnect structure is one of a via and a trench.

4. A semiconductor device as recited in claim 1, further comprising:
a copper layer formed over the barrier layer and filling the damascene interconnect structure; and
a cap layer deposited over the copper layer and the barrier layer.

5. A semiconductor device as recited in claim 1, wherein the barrier layer is made from at least one of Ta, W, Ru, Rh, Co, and Ni.

6. A semiconductor device as recited in claim 1, wherein the barrier layer is between 100 Angstroms to 500 Angstroms in thickness.

7. A semiconductor device as recited in claim 1, wherein the barrier layer is between 200 Angstroms and 250 Angstroms in thickness.

8. A semiconductor device as recited in claim 1, wherein the dielectric layer is one of a silicon dioxide and a low-k dielectric.

9. A method for making a semiconductor device, comprising:
providing a substrate;
forming a dielectric layer over the substrate;
defining a damascene interconnect structure in the dielectric layer; and
forming a barrier layer over the dielectric layer and within the damascene interconnect structure, the barrier layer being tapered within the damascene interconnect structure.

10. A method for making a semiconductor device as recited in claim 9, wherein defining the damascene interconnect structure includes defining one of a via and a trench.

11. A method for making a semiconductor device as recited in claim 9, further comprising:
depositing a metal layer over the dielectric layer and the damascene interconnect structure;
planarizing the metal layer; and
applying a cap layer over the planarized metal layer and the barrier layer.

12. A method for making a semiconductor device as recited in claim 9, wherein forming a barrier layer over the dielectric layer and within the damascene interconnect structure includes,
depositing a barrier layer over the dielectric layer and within the damascene interconnect structure; and
plasma etching the barrier layer while applying a voltage to the substrate, the voltage being a negative potential.

13. A method for making a semiconductor device as recited in claim 9, wherein forming a barrier layer over the dielectric layer and within the damascene interconnect structure includes,
depositing a barrier layer over the dielectric layer and within the damascene interconnect structure; and
electrochemically etching the barrier layer while applying a voltage to the substrate, the voltage being a positive potential.

14. A method for making a semiconductor device as recited in claim 9, wherein forming the barrier layer includes applying a voltage to the substrate through a substrate holder during an etching operation.

15. A method for making a semiconductor device as recited in claim 9, wherein the method further includes forming the barrier layer using at least one of Ta, W, Ru, Rh, Co, and Ni.

16. A semiconductor device as recited in claim 9, wherein the method further includes forming the barrier layer between 100 Angstroms to about 500 Angstroms in thickness.

17. A method for making a semiconductor device as recited in claim 9, further comprising:
depositing a copper seed layer over the dielectric layer and within the damascene interconnect structure;
depositing a copper layer over the copper seed layer to fill the damascene interconnect structure;
planarizing the copper layer; and
applying a cap layer over the planarized copper layer and the barrier layer.

18. A method for making a semiconductor device, comprising:
providing a substrate;
forming a dielectric layer over the substrate;
defining one of a via and a trench in the dielectric layer;
depositing a barrier layer over the dielectric layer and within the damascene interconnect structure; and
etching the barrier layer while applying a voltage to the substrate, the etching generating a tapered barrier layer within the damascene interconnect structure.

19. A method for making a semiconductor device as recited in claim 18, wherein the etching is a plasma etching and the voltage applied is a negative potential.

20. A method for making a semiconductor device as recited in claim 18, wherein the etching is a chemical etching and the voltage applied is a positive potential.

21. A system with a damascene interconnect structure, comprising:
a microprocessor including a damascene interconnect structure with a tapered barrier layer within the damascene interconnect structure;
a bus coupled to the microprocessor; and
a network interface coupled to the bus.

22. A system with a damascene interconnect structure as recited in claim 21, wherein the tapered barrier layer is generated by application of a voltage to the damascene interconnect structure during etching of the barrier.

23. A system with a damascene interconnect structure as recited in claim 22, wherein the etching includes one of a plasma etching and an electrochemical etching.

24. A system with a damascene interconnect structure as recited in claim 23, wherein a negative potential is applied when the plasma etching is used and a positive potential is applied when the electrochemical etching is used.
